(19) United States
(12) Patent Application Publication
(10) Pub. No.: US 2009/0021300 A1
(43) Pub. Date: Jan. 22, 2009

(54) Apparatus and Method for Detecting Output Power From an Amplifier

(76) Inventor: Antonio Romano, Ashton (CA)

Correspondence Address: Ralph A. Dowell of DOWELL & DOWELL P.C., 2111 Eisenhower Ave, Suite 406, Alexandria, VA, 22314, US

(21) Appl. No.: 12/224,325

(22) PCT Filed: Feb. 26, 2007
(86) PCT No.: PCT/CA2007/000300

§ 371 Date: Aug. 25, 2008

Related U.S. Application Data
(60) Provisional application No. 60/776,203, filed on Feb. 24, 2006.

(51) Int. Cl. G01R 21/06

(52) U.S. Cl. 330/2

(57) ABSTRACT

An apparatus for detecting output power from an amplifier (103) comprises a first controller (105) for controlling output power of a signal from the amplifier (103), a device (107) for measuring dc bias current/voltage at an output (115) of the amplifier (103), second controller (109) operative to set the first controller (105) to a setting corresponding to an output power at a finite level, and a detector (109) for determining whether or not there is output power from the amplifier based on the measured dc bias current/voltage at the setting of the first controller (105). In one embodiment, the first controller (105) is set at a setting corresponding to an output power level which is sufficient to at least partially saturate the amplifier (103).

### FIELD OF THE INVENTION

The present invention relates to apparatus and methods for detecting output power from an amplifier, and in particular, but not limited to detecting output power from a power amplifier of a radio transmitter.

### BACKGROUND OF THE INVENTION

A typical radio transmitter for use in wireless communication networks is shown in FIG. 1. The transmitter 1 comprises an upconverter 3 which includes a mixer 5 having a signal input 7 and a local oscillator 9, a filter 11, a power amplifier 13 and an antenna 15. The transmitter further comprises a DC bias current controller 17, a DC bias current measurement device 19 and a power sensor 21 coupled to the output 23 of the amplifier for measuring the output power of the amplifier 13. The upconverter may have a number of mixers so that upconversion is performed in multiple stages, and an additional filter(s) may be included between one mixer stage and another. A filter may also be inserted between the power amplifier 13 and the antenna 15. If the radio transmitter is part of a transceiver, a diplexer waveguide may be positioned between the power sensor and antenna.

During manufacture of the radio transmitter, the amplifier is factory tuned to the required operating point by adjusting the DC bias current to the appropriate value using the DC bias current controller 17 and DC bias current measuring device 19. Also during manufacture, the amplifier output power is detected and measured by the power sensor 21 to check that the transmitter is operating correctly. The power sensor is also typically used for diagnostic testing and to detect transmitter operating problems during the normal course of operation of the transmitter.

A drawback of this current arrangement is that the power sensor, which typically comprises an RF coupler, a Schottky diode and a DC amplifier, draws power from the output of the power amplifier, thereby reducing the power of the signal to the antenna 15. This is predominantly caused by the rf coupler which adds insertion loss between the amplifier and antenna. A further drawback of this arrangement is that the power sensor takes up additional space between the output of the amplifier and the antenna and adds cost to the transmitter.

### SUMMARY OF THE INVENTION

According to the present invention, there is provided an apparatus for detecting output power of a signal from an amplifier, comprising: a first controller for controlling output power of the signal from said amplifier; measuring means for measuring DC bias current/voltage associated with (e.g. at an output of) said amplifier; a second controller operative to control said first controller to set said output power at a finite, possibly predetermined level; and determining means for determining whether or not there is output power from said amplifier based on the measured DC bias current/voltage at said finite, possibly predetermined level.

In this arrangement, detection of output power from the amplifier is based on the dependency of DC bias current on output power level. This dependency makes it possible to select a predetermined setting for the first controller which is expected to provide a predetermined output power from the amplifier and a related value of DC bias current. Thus by measuring the DC bias current at the predetermined level, the apparatus is capable of detecting whether or not there is output power from the amplifier, and in some embodiments, where the DC bias current is calibrated to the output power, the apparatus may be used to measure the output power from the amplifier. The first controller should be set at a setting which is expected to produce at least a finite (i.e. non-zero) output power, but not necessarily at a setting corresponding to a predetermined or particular value of output power. The measuring means may be adapted to measure the dc bias current/voltage at an output of the amplifier.

In some embodiments, the predetermined level is selected to provide a DC bias current/voltage different from that at a lower output power level. For example, the predetermined level may be sufficient to at least partially saturate the amplifier. As the amplifier is driven towards saturation, the DC bias current may exhibit a non-linear dependency on output power level, and the DC bias current can change significantly in this region, facilitating the detection of output power from the amplifier.

In some embodiments, the determining means is adapted to make the determination based on a set value. For example, the determining means may compare the measured DC bias current level with a set value. The set value may be any suitable value, such as the value of DC bias current when no signal or a low signal is applied to the input of the amplifier, or an expected value of DC bias current at a finite, possibly predetermined output level.

In some embodiments, the second controller is adapted to control the first controller to successively set the output power at the predetermined level and a second level, different from the predetermined level, and the determining means is adapted to determine whether or not there is output power from the amplifier based on the measured DC bias current/voltage at the different levels.

In this arrangement, detection of output power from the amplifier is based on the variation of DC bias current with output power level. The second controller is adapted to set the first controller to provide a first output power level and the DC bias current at that power level is measured by the measuring means. The second controller then sets the first controller to provide a different output power level and the DC bias current at that second level is also measured. The determining means then determines whether or not there is output power from the amplifier based on the measured values of DC bias current at the two different settings of the first controller.

In some embodiments, the determining means determines that there is output power if the values of DC bias current/voltage are different.

In some embodiments, the determining means comprises ratio determining means for determining the ratio of the first and second measured values of DC bias current/voltage. Advantageously, determining the ratio of measured bias current/voltage assists in removing temperature dependency of bias current/voltage from the measurement, and may also help to remove its dependency on other factors such as those connected with ageing and use.

In some embodiments, the determining means further comprises comparing means for comparing the ratio with a predetermined value.

The determining means may determine that there is output power from the amplifier if the measured ratio equals or exceeds the predetermined value.

In some embodiments, the apparatus includes an interface for receiving a user command, and the second controller is responsive to the user command to successively set the output power at the first and second different levels.

In this embodiment, a single input command can cause the apparatus to perform the sequence of steps required to detect whether or not there is power at the output of the amplifier.

In some embodiments, the apparatus further comprises indicator means for indicating whether or not there is output power from the amplifier as determined by the determining means. The indicator may comprise any suitable form of indicator such as a visual and/or audible indicator. In a basic embodiment, the indicator may include a simple light which is turned on if power is detected and remains off if power is not detected (or vice versa). Alternatively, or in addition, the indicator may provide one or more values based on the measured values of DC bias current, and in one embodiment, may provide the value of the bias current ratio. In another embodiment, where the relationship between DC bias current and output power level can be quantitatively evaluated, the visual indicator may provide a value of output power.

In some embodiments, the apparatus further comprises means for determining the value of at least one of the first and second output power levels based on the value of another parameter. In some embodiments, the other parameter comprises an operating parameter for the amplifier, for example a maximum (and/or minimum) value for the output power. Advantageously, this arrangement enables an appropriate setting of first and/or second output power levels for the first controller to be determined and used by the second controller to adjust the first controller to that or those settings in order to perform the output power detection. This obviates the need for the operator to make this determination and helps prevent incorrect settings, such as settings that exceed the maximum power level, from being used in detecting the output power and potentially causing damage to the amplifier and/or transmitter.

In some embodiments, the first controller comprises at least one of a controller for controlling the level of input signal to the amplifier and a gain controller for controlling the gain of the amplifier. For example, the controller may comprise a variable attenuator (or separate variable gain amplifier) for attenuating or varying the input signal level. Alternatively, or in addition, the controller may be implemented by modulating a tone or other signal, and controlling the amplitude of modulation. Alternatively or in addition, the gain of the amplifier whose output power is being detected may be varied, but this may also change other operating parameters of the amplifier.

The means for measuring dc bias current/voltage may comprise any suitable device. In some embodiments, the measuring means comprises resistance means, for example comprising one or more resistor(s) for carrying the DC bias current, and means for measuring the voltage across the resistance means.

Advantageously, where embodiments of the invention are implemented with an amplifier provided with a measuring device for measuring DC bias current, the same DC bias current measurement device can be used in the detection of output power from the amplifier, thereby reducing the number of components required for the detector.

In some embodiments, the apparatus further comprises means for determining the value of output power from the amplifier based on at least one measured value of DC bias current/voltage. In this embodiment, by pre-calibrating at least one value of DC bias current to the output power level, the measured DC bias current can be used to measure the output power level.

In some embodiments, the determining means is adapted to determine the value of output power from the amplifier based on a predetermined relationship between output power and DC bias current/voltage. The relationship may be defined by a mathematical expression such as a polynomial regression fitted to data points to produce a calibration curve, or may be stored as a table of DC current/voltage and corresponding output power levels, for example recorded in a look-up table in a memory or other storage device or medium.

Thus, according to another aspect of the present invention, there is provided an apparatus for measuring output power from an amplifier, comprising measuring means for measuring DC bias current/voltage of the amplifier, and determining means for determining from the measured bias current/voltage the value of output power from the amplifier.

Also according to the present invention, there is provided a method of detecting output power from an amplifier comprising the steps of: (a) supplying an input signal to be amplified to said amplifier; (b) setting a controller for controlling output power from said amplifier to a setting corresponding to a finite, possibly predetermined level of output power from the amplifier; (c) measuring the DC bias current/voltage associated with (e.g. at an output of) said amplifier at said setting (or predetermined level); and (d) determining whether or not there is output power from said amplifier based on said value of DC bias current/voltage measured at said setting (or predetermined level).

In some embodiments, the predetermined level is selected to provide a value of DC bias current/voltage that can be distinguished from another value of DC bias current/voltage if there is output power from the amplifier. For example, the predetermined level may be sufficient to at least partially saturate the amplifier.

In some embodiments, the determining step comprises making the determination based on a set value. For example, the set value may be a value of DC bias current when there is no signal or a low signal applied to the input of the amplifier, or an expected value of DC bias current for the predetermined output power level.

In some embodiments, the method further comprises (e) setting a controller for controlling output power from the amplifier to a second setting corresponding to a second (e.g. finite) level of output power from the amplifier, the second level being different from the first predetermined level, (f) measuring the DC bias current/voltage at an output of the amplifier at the second setting (or second output power level), and (g) making the determination based on the measured DC bias current/voltage at the second setting (or level).

In some embodiments, the first and second different levels of output power are selected to cause the DC bias current/voltage to have different values at the first and second levels if there is output power from the amplifier.

In some embodiments, the step of determining comprises determining that there is output power if the values of DC bias current/voltage are different.

In some embodiments, the step of determining comprises determining the ratio of the first and second measured values of DC bias current/voltage.

In some embodiments, the step of determining further comprises comparing the ratio with a predetermined value.

In some embodiments, the step of determining comprises determining that there is output power from the amplifier if the measured ratio equals or exceeds a predetermined value.

In some embodiments, the method further comprises performing at least steps (b) and (e) described above in response to a single user input command.

In some embodiments, the method further comprises providing an indication detectable by a user as to whether or not there is output power from the amplifier as determined by the determining step.

In some embodiments, the method further comprises determining the value of at least one of the first and second output levels based on the value of another parameter. For example, the other parameter may comprise an operating parameter of the amplifier such as a maximum (and/or minimum) value for the output power.

In some embodiments, the controller in step (b) comprises at least one of a gain controller for controlling the gain of the amplifier and a controller for controlling the level of input signal to the amplifier.

In some embodiments, the controller for controlling output power from the amplifier in step (e) comprises at least one of a gain controller for controlling the gain of the amplifier and a controller for controlling the level of input signal to the amplifier. In some embodiments, the controller in step (e) may be the same as that in step (b) or the controller may be different.

In some embodiments, the method includes measuring the DC bias current/voltage in at least one of steps (c) and (f) by measuring the voltage across a resistance means, e.g. one or more resistor(s) carrying the DC bias current.

In some embodiments, the method further comprises selecting an operating point for the amplifier in which the value of DC bias current/voltage is greater at a predetermined output power level than the DC bias level at the predetermined output level for another operating point. Advantageously, the operating point can be selected to improve the sensitivity of the detector. The operating point may be adjusted by selecting an appropriate DC bias level.

In some embodiments, the method further comprises determining the value of output power from the amplifier based on a measured value of DC bias current/voltage. For example, the determination may be made using a predetermined relationship between DC bias current/voltage and output power level.

Thus, according to another aspect of the present invention, there is provided a method of detecting output power from an amplifier comprising applying a signal to be amplified to the amplifier, the signal being conditioned to provide a finite, possibly predetermined output power from the amplifier, measuring bias current/voltage of the amplifier, and determining if there is power from the amplifier based on the value of the measured DC bias current/voltage.

According to another aspect of the present invention, there is provided a method of measuring the output power from an amplifier, comprising applying a signal to be amplified to the amplifier, measuring bias current/voltage of the amplifier when applying the signal, and determining the value of output power from the amplifier, or a parameter based thereon, based on the measured value of bias current/voltage. In some embodiments, the determination is based on a predetermined relationship between bias current/voltage and output power. In some embodiments, the predetermined relationship comprises at least one of a table of values of bias current/voltage and corresponding values of output power or a parameter based thereon, and a mathematical relationship.

In some embodiments, the signal applied to the amplifier comprises a modulated tone. Advantageously, modulation may be applied to the signal tone (e.g. carrier wave tone) in order to control (e.g. increase) the power of the output signal from the amplifier, to assist in detection of output power from the amplifier.

According to another aspect of the present invention, there is provided a machine readable medium, including a data structure comprising one or more values of bias current/voltage and corresponding values of amplifier output power or a parameter associated therewith.

According to another aspect of the present invention, there is provided a device for determining values of a parameter, said device having access to means defining a relationship between a first parameter and a second parameter, said first parameter comprising bias current/voltage of an amplifier and the second parameter comprising output power from said amplifier or parameter associated therewith, wherein said device is responsive to a command which includes a value of one of said first and second parameters to provide a corresponding value of the other of said first and second parameters as defined by said relationship.

According to another aspect of the present invention, there is provided an apparatus for detecting output power from an active device, comprising sensor means for sensing a parameter associated with said device, said parameter being different from and dependent on output power from the device, and determining means for making a determination indicative of whether there is output power from the device based on the value of the sensed parameter.

In one embodiment, the parameter comprises any one of: (a) a temperature of said device; (b) bias voltage of a control terminal (e.g. gate, base or grid) of the device; (c) bias current to a control terminal (e.g. gate, base or grid) of the device; (d) DC or low frequency current through a non-control terminal (e.g. drain, source, collector, emitter, anode, cathode) of said device; and (e) DC or low frequency voltage of a non-control terminal (e.g. drain, source, collector, emitter, anode, cathode) of said device.

In some embodiments, the apparatus further comprises means for applying a low frequency signal to said device, wherein said sensor is adapted to measure a resulting low frequency signal output from a terminal of said device.

In some embodiments, the means for applying a low frequency signal comprises means for applying first and second signals to the device, wherein the second signal has a different frequency to the first signal. In this embodiment, the low frequency is the difference between the first and second frequencies. The first and second frequencies may have any suitable values, and can be selected to be sufficiently high to pass through any DC blocking capacitors in the signal path.

As used herein amplifier means any device capable of amplifying a signal, including an amplifier stage of a multi-stage amplifier or a single stage amplifier.

As used herein bias voltage in the expression bias current/voltage means the voltage produced by the current when the current is passed through a resistance means, e.g. resistor or resistors, as distinct from a bias voltage applied to a control terminal of an active device of the amplifier.

### BRIEF DESCRIPTION OF THE DRAWINGS

Examples of embodiments of the present invention will now be described with reference to the drawings, in which:

FIG. 1 shows a schematic diagram of a radio transmitter according to the prior art;

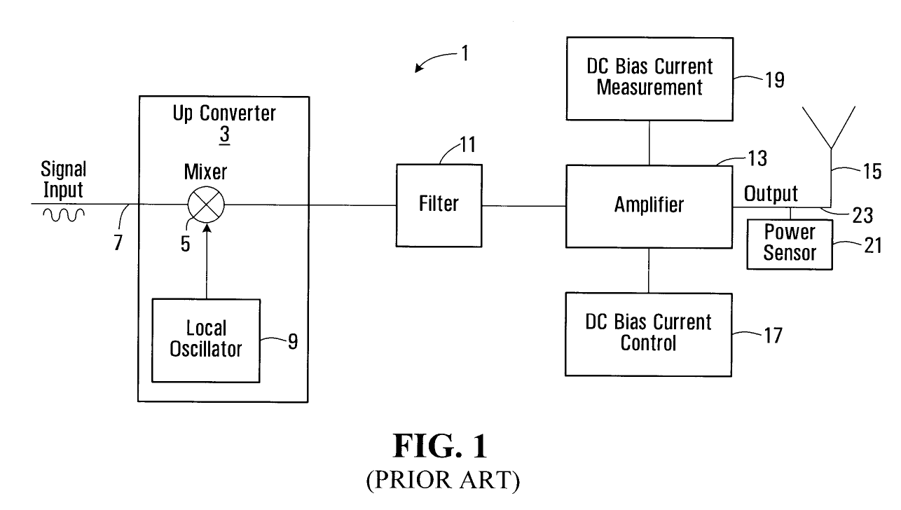

FIG. 2 shows a block diagram of an apparatus according to an embodiment of the present invention;

FIG. 3 shows an example of a graph of the relationship between bias current and output power of an amplifier;

FIG. 4 shows a schematic diagram of an apparatus according to another embodiment of the invention;

FIG. 5 shows a schematic diagram of another embodiment of the invention; and

FIG. 6 shows a schematic diagram of another embodiment of the invention.

### DESCRIPTION OF EMBODIMENTS

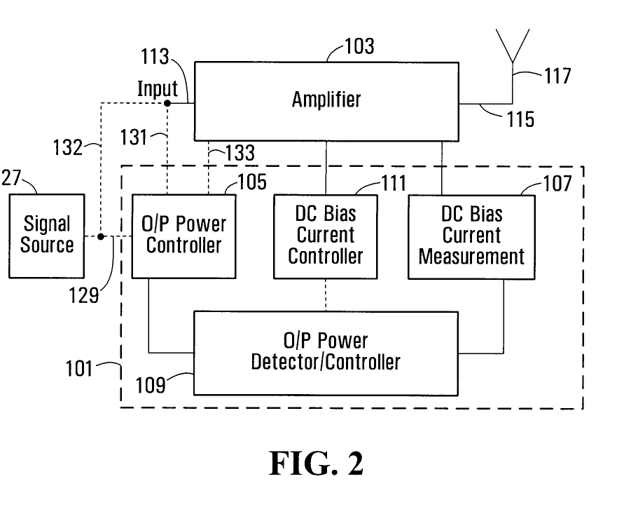

Referring to FIG. 2, an apparatus 101 for detecting output power from an amplifier 103 comprises an output power controller 105 for controlling the output power from the amplifier, a DC bias current measuring device 107 for measuring DC bias current/voltage at an output 115 from the amplifier 103 and an output power detector/controller 109 for detecting output power from the amplifier. The output power detector 109 is configured to control the output power controller 105 to implement the detection method, as described in more detail below, and to determine whether or not there is output power from the amplifier based on DC bias current measurement(s) made by the bias current measurement device 107.

A dc voltage source is typically provided to bias the amplifier, the voltage source providing either a fixed voltage or variable voltage.

The apparatus 101 may optionally include a DC bias current controller 111, which may be controllable by an operator and/or by the output power detector 109, or some other device. The controller 111 may be operative to control the dc voltage source. The amplifier has an input 113 for receiving an input signal to be amplified from a suitable signal source 127, and in this embodiment, the output of the amplifier is connected to an antenna 17, although in other arrangements, the amplifier may be coupled to any other desired component or load.

The output power controller 105 may comprise any suitable controller for controlling the output power from the amplifier. Non-limiting examples include a controller for controlling the amplitude of the input signal and a gain controller for controlling the gain of the amplifier. The controller for controlling the amplitude of the input signal may comprise an attenuator and/or a variable gain amplifier. In embodiments in which the output power controller controls the input signal level, the controller 105 receives a signal from the signal source 127, e.g. via path 129 and passes the amplitude-conditioned signal to the input 113 of the amplifier via path 131. In embodiments in which the output power controller controls the gain of the amplifier 103, and not the input signal, the signal source 127 may be connected directly to the input 113 of the amplifier 103, e.g. via path 132 and the gain controller may control the gain via control path 133, for example. In other embodiments, the output power controller may control both the input signal level and the gain of the amplifier.

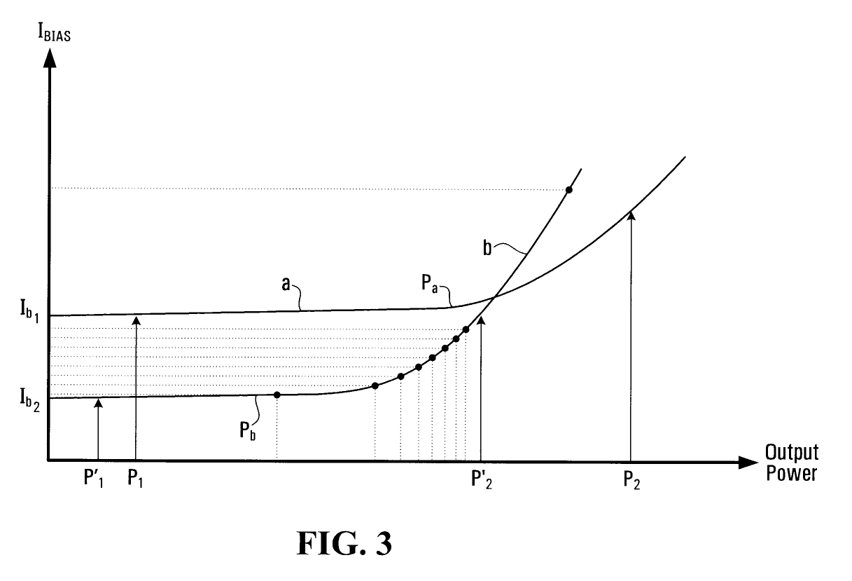

FIG. 3 shows an example of a graph of the relationship between DC bias current and amplifier output power. The graph shows two curves a, b of DC bias current as a function of output power for two different DC bias current settings I_{b1} and I_{b2}, respectively. The DC bias current settings, I_{b1} and I_{b2} may typically be the values of DC bias current in the absence of an input signal to the amplifier. As indicated by curve a, the bias current for the higher bias current setting I_{b1} is substantially constant or varies very little with output power up to an output power level Pₐ, beyond which the DC bias current increases substantially and, in this example, non-linearly with increased output power. As indicated by curve b, for the lower bias current setting, the bias current is substantially constant or varies very little with increasing output power to a power level P_{b}, beyond which the bias current increases substantially and, in this example, non-linearly with increased output power. The increase of bias current with output power in the non-linear region of each curve, a, b, occurs as the amplifier is driven towards and into saturation. Curve b indicates that for a lower bias current setting, the non-linear relationship between bias current and output power occurs at lower output power levels than for higher DC bias current settings. Embodiments of the output power detection apparatus use the relationship between DC bias current and output power to detect whether or not there is output power from the amplifier. In further embodiments, the relationship between DC bias current and output power may be used to measure the value of output power from the amplifier.

Examples of operation of the apparatus to detect output power will now be described with reference to FIGS. 2 and 3.

Initially, the DC bias current is set to a desired value, for example I_{b1}. The bias current level may be determined by an operator, or determined automatically by some other means. An input signal is fed to the input 113 of the amplifier 103 and the output power controller 105 is set to provide an output power at a first output power level, for example P₁ (FIG. 3). The value of DC bias current (or voltage equivalent) is measured at the first power level setting of the power controller by the bias current measurement device 107 and the measured value is passed to the output power detector 109.

The output power controller is then set to provide a different amplifier output power level, for example power level P₂ (FIG. 3). In the present embodiment, the power controller is set to the second level by the power detector 109, although in other embodiments, the second power level may be set by an operator or by other means. The first and second power levels are selected to cause the DC bias current/voltage to have different values at the first and second power levels if there is output power from the amplifier. In this particular embodiment, the second output power level is selected such that the DC bias current is expected to be higher than the DC bias current at the first power level P₁ if there is output power from the amplifier. The DC bias current at the second output power level is measured by the DC bias current measuring device 107 and the measured value is passed to the output power detector 109. The output power detector 109 is configured to determine whether or not there is power at the output of the amplifier based on the measured DC bias current/voltage at the first and second power levels. This determination may be made using any suitable method in which these values can be used to make such a determination. For example, in one embodiment, the power detector may make a simple comparison between the two values and if the values are sufficiently different, the power detector may determine that there is output power from the amplifier. If the difference between the two values of DC bias current are not sufficiently different, the output power detector may determine that there is no power from the amplifier or that there is power but the power level is below an expected value, possibly indicating a problem with the amplifier or with one or more other components associated with the amplifier, for example, component(s) of an RF transmitter in which the amplifier is implemented, a problem at any other position in the signal path prior to the amplifier, or with the input signal drive circuitry. In another embodiment, the ratio of the two measured bias current values may be determined and compared with a predetermined value for the ratio. The result of the comparison is then used to determine if there is power at the output of the amplifier. Using the ratio as the relevant parameter helps to eliminate temperature dependency and possibly other factors from the measurement.

To increase the sensitivity of the measurement, the DC bias current setting may be adjusted to a lower value, for example to a value corresponding to the quiescent (or small signal) operating point of the amplifier. Thus for example referring again to FIGS. 2 and 3, the DC bias current may initially be set to a lower value, for example I_{b2}. The output power controller is set to provide a first value of output power, for example P₁′, and the DC bias current is measured at this level. The output power controller is then set to provide a second output power level P₂′ (FIG. 3) and the DC bias current at this second level is also measured. Again, the first and second power levels are selected to cause the DC bias current to have different values if there is output power from the amplifier. In this particular example, the value of P₂′ corresponds to a higher DC bias current level than the first output power level P₁′. The output power detector 109 determines whether there is output power from the amplifier based on the measured first and second values of DC bias current. As indicated above, the determination may be made using any suitable technique, such as a simple comparison between the two values, and/or by determining the ratio of the bias current values and comparing the ratio with a predetermined threshold value.

It will be appreciated that any suitable values of power level may be selected to measure the DC bias current. For example, one DC bias current measurement may be made at a power level in the range where the DC bias current is substantially constant with output power, and the other measurement may be made where the DC bias current increases with output power (for example in the non-linear region). Alternatively, both DC bias current measurements may be made in the region where DC bias current increases with output power. It will be appreciated that the DC bias currents may be measured in either order so that the DC bias current is measured at the higher output power level first and a lower output level second, or vice versa.

In other embodiments, output power may be detected by measuring the value of bias current at a single output power level setting. For example, a single measurement may be made in a region where bias current changes significantly with output power level. The measured value can then be compared to a set value, and the result of the comparison used to determine whether or not there is output power from the amplifier.

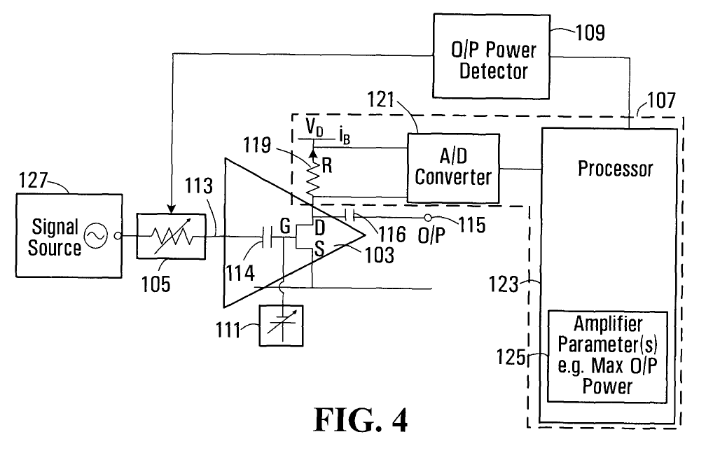

FIG. 4 shows an example of an output power detector apparatus in more detail. The apparatus is similar to the embodiment shown in FIG. 2, and like components are designated by the same reference numerals.

The amplifier 103 comprises an active device such as a field effect transistor (FET) having a gate G, source S, and drain D. The input 113 of the amplifier is connected to the gate, G, via a DC blocking capacitor 114, and the output 115 of the amplifier is connected to the drain, D, via a DC blocking capacitor 116. The drain of the FET is also connected to a voltage rail, V_{D}, via a resistor 119. The DC bias current controller 111 provides a variable DC bias voltage to the gate of the FET. The current controller 111 may be implemented by any suitable means, for example by a variable voltage source and/or variable resistor and/or potentiometer or potential divider, and/or any other suitable means known to those skilled in the art.

In this embodiment, the DC bias current measurement device 107 comprises a voltage sensor and A to D converter 121 for measuring the voltage across the resistor 119 through which the DC bias current flows, and a processor 123. In this embodiment, the DC bias current is measured by measuring the voltage across the resistor 119 and dividing the measured voltage drop by the resistance of the resistor to obtain the DC bias current according to Ohm's law, as is well known to those skilled in the art. The conversion from measured voltage to current may be performed by the processor 123. Alternatively, since the voltage drop across the resistor is proportional to the DC bias current, the values of voltage may be used instead of DC current values in the detection of output power.

In this embodiment, the output power controller 105 comprises a variable attenuator for controlling the amplitude of the input signal to the amplifier. The attenuator may comprise a signal-controlled attenuator, and in this embodiment, the attenuator is controlled by a signal from the output power detector 109. In one example of operation, the power detector 109 controls the variable attenuator 105 by setting the input signal level at a first setting to provide a first output power level, and then changes the input signal level to a second setting to provide a second output power level at the output of the amplifier. As described above, the DC bias current/voltage is measured at each input signal setting, and the power detector determines from these measured values whether or not there is power at the output of the amplifier.

In another example of operation, the power detector controls the attenuator to set the O/P power level at a single value of O/P power at which a bias current is measured. The single measurement is used to detect O/P power from the amplifier, as described above, for example.

The processor 123 may include the value of any one or more parameters of the amplifier, for example, operating parameters such as the maximum output power. The processor may be configured to provide any one or more of these parameters to the output power detector 109 in order to determine suitable values for the first and/or second output power levels for setting the output power level controller when detecting output power from the amplifier.

In other embodiments, the amplifier parameter(s) may be provided to the output power detector 109 from any other source.

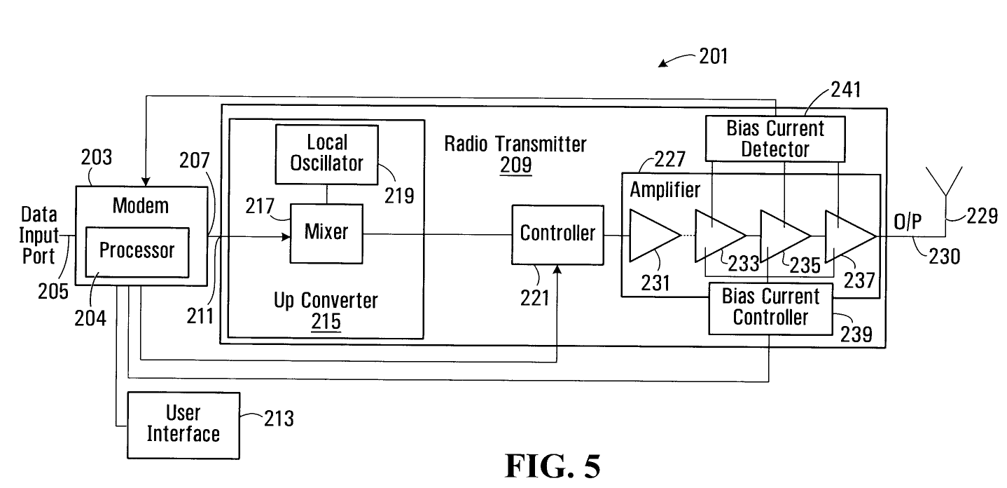

The output power detection apparatus according to embodiments of the present invention may be implemented to detect the power output from any one or more stages of a multi-stage amplifier. An example of an embodiment of the power detection system implemented in a radio transmitter having a multi-stage amplifier is shown in FIG. 5. Referring to FIG. 5, a communication system, generally shown at 201, comprises a modem 203 having one or more data input port(s) 205 and a data output port 207, a radio transmitter 209 having an input port 211 connected to the output port of the modem, and a user interface 213 connected to the modem. The radio transmitter 209 comprises an upconverter 215, which includes one or more mixer stages, each having a mixer 217 and local oscillator 219 (or other signal source), a controller 221 connected to the output of the upconverter 215, an amplifier 227 connected to the output of the controller 221, and an antenna 229 connected to the output 230 of the amplifier. The radio transmitter may optionally include one or more filters in the signal path, for example, at the output of and/or between mixer stages (if more than one) of the upconverter, and/or between the amplifier and the antenna.

The amplifier comprises a plurality of amplifier stages 231, 233, 235, 237, a DC bias current controller 239 for controlling the DC bias current applied to one or more stages of the amplifier, and a DC bias current measurement device 241 for measuring the DC bias current of one or more amplifier stages. In this particular embodiment, the DC bias current controller is configured to control the bias current through the last three amplifier stages 233, 235, 237. If appropriate to do so, the control terminal (e.g. gate or base) of each amplifier active device, may be biased by the same DC voltage, for example, if each amplifier stage shares the same physical characteristics, as may be the case where each stage is fabricated on the same monolithic chip. In other embodiments, the DC bias current controller may be adapted to provide different DC bias voltages to different amplifier stages.

In this embodiment, the DC bias current from the last three amplifier stages is measured by the bias current measurement device 241. In one implementation, the bias current measurement device is adapted to measure the accumulative DC bias current from all three stages. In another implementation, the bias current measurement device 241 may be adapted to measure the DC bias current of one or more stages separately. An example of how the apparatus operates to detect the presence or absence of output power from the amplifier is described below.

A signal is applied to the input of the amplifier 227. The signal may comprise a CW (carrier wave) tone, or a modulated carrier wave signal. The original signal may be generated by the local oscillator 217, and/or by the modem 203.

The value of any operating parameters of the amplifier which may be useful in determining appropriate power amplifier output levels and/or DC bias current levels for detecting output power from the amplifier may be provided by the radio transmitter to the modem, and the modem may determine the appropriate level(s) from these value(s). Alternatively, appropriate values for the output power level of the amplifier may be provided to the modem by an operator via the user interface 213, or by some other means.

The modem controls the DC bias current controller to set the bias current to the appropriate value and also controls the controller 221 to apply the appropriate level of input signal to the amplifier to provide a first level of output power from the amplifier. The bias current measuring device 241 measures the bias current and transmits this information to the modem. The modem then controls the controller 221 to change the input signal level to provide a second level of output power from the amplifier, the DC bias current is measured at the controller setting and provided to the modem. The modem processor 204 then determines whether or not there is output power from the amplifier based on the measured values of DC bias current at the two different settings of the controller 221. The modem may provide an indication to the user interface and/or to another device as to whether or not there is output power from the amplifier.

The controller 221 may be implemented by any suitable means, and may, for example, comprise a variable attenuator and/or a variable gain amplifier for controlling the amplitude of the signal to the input of the amplifier 227. The controller 221 may also be arranged in any suitable position where it is capable of varying the input signal level to the amplifier. For example, the controller may be positioned at the input of the radio transmitter or between any mixer stages of the upconverter, between any stages of the amplifier or at any other suitable position in the signal path.

In other embodiments, the modem may be configured to determine whether or not there is output power from the amplifier using a value of bias current measured at a single output power level setting, as for example described above.

Some embodiments may be implemented to use the variation of DC bias current with output power to measure the value of output power from the amplifier. For example, the variation of DC bias current with output power may be measured using a suitable output power measuring device as the output power is varied for a given initial DC bias current setting. The value of DC bias current for each measured output power level is recorded (for example, as shown by the dotted lines in FIG. 3), and this data may subsequently be used to determine the output power level from a measured value of DC bias current. In calibrating the DC bias current to the output power level, a polynomial regression may be fitted to the data points and subsequently used to calculate the output power from a given value of DC bias current. Alternatively, output power levels corresponding to a range of different DC bias current values may be recorded in a database such as a lookup table and used to determine output power from a measured value of DC bias current. DC bias current may be calibrated against output power for any number of different DC bias settings.

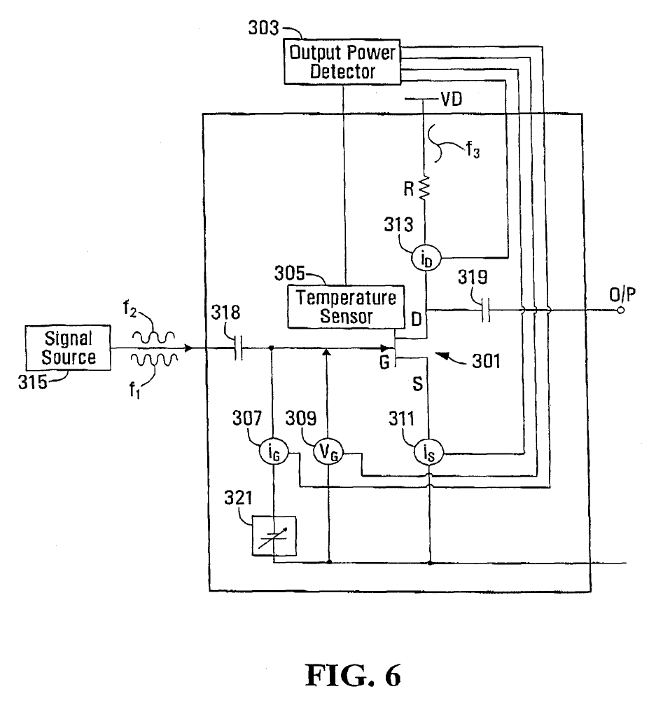

In another aspects and embodiments of the invention, output power from an active device, whether or not implemented in an amplifier, may be detected by sensing any parameter associated with the device in which the parameter is different from and dependent on output power from the device. Thus, another aspect of the invention provides an apparatus for detecting output power from an active device, comprising sensor means for sensing a parameter associated with the device, the parameter being different from and dependent on output power from the device, and determining means for making a determination indicative of whether there is output power from the device based on the value of the sensed parameter. In embodiments of the apparatus, the sensed parameter may comprise any of: (a) a temperature of the device; (b) bias voltage of a control terminal (e.g. gate, base or grid) of the device; (c) bias current to a control terminal (e.g. gate, base or grid) of the device; (d) DC or low frequency current through a non-control terminal (e.g. drain, source, collector, emitter, anode, cathode) of the device; and (e) DC or low frequency voltage of a non-control terminal (e.g. drain, source, collector, emitter, anode, cathode) of the device, or any other suitable parameter. Examples of embodiments of the apparatus are shown in FIG. 6.

FIG. 6 shows an active device 301, which in this example comprises a field effect transistor having a gate, G, a source, S, and a drain, D, and whose output power is to be detected. The output power detection apparatus comprises one or more sensors for sensing a parameter indicative of output power from the device, and an output power detector 303. Examples of the sensors include, but are not limited to a temperature sensor 305 for sensing the temperature of the device, and which may comprise any suitable temperature sensor such as a thermo-couple or other infrared temperature sensor, a gate current sensor 307 for detecting the gate current (e.g. DC bias current applied through the gate), a voltage sensor 309 for sensing the voltage at the gate, a source current detector 311 for detecting source current, and a drain current detector 313 for detecting drain current. Each selected sensor is connected to the output power detector 303 (or if there is more than one output power detector, different sensors may be connected to different detectors). Any of the above parameters can be indicative of whether there is output power at the output of the active device. The value of the detected parameter is passed to the output power detector 303 which determines from the value of the parameter whether there is output power from the device. The output power detector may make this determination by comparing the value of the parameter or a derivative thereof with a predetermined value for the parameter or derivative thereof, where the result of the comparison is determinative of whether there is output power from the device.

In one embodiment, a low frequency signal may be applied to the control terminal (e.g. gate) of the device and the low frequency current and/or voltage at a non-control terminal of the device (e.g. drain) can be measured to indicate whether there is output power from the device. Referring again to FIG. 6, in one embodiment, a signal comprising two frequencies (for example two tones) f₁, f₂ may be applied to the gate of the FET from a suitable signal source 315. The low frequency signal (e.g. f₃) is the signal produced by inter-modulation of the two different frequency signals and has a frequency equal to the difference between the two higher frequencies (e.g. f₁-f₂=f₃). Thus, the two frequencies may be chosen so that their difference is relatively small, for example 1 kHz (or any other suitable value) to produce a low frequency drain current of the same frequency. This low frequency current (or voltage produced thereby) can be measured using an appropriate sensor, for example drain current sensor 313. The two source frequencies can be chosen to be sufficiently high that the signal amplitudes are not significantly attenuated by the DC blocking capacitor. In some embodiments, which include a filter between the DC bias source and ground, the filter can be configured and the frequency difference selected so that the filter does not pass or does not significantly pass the low frequency signal to ground. This can be achieved by using a sufficiently small spacing between the frequencies (so that the capacitive impedance of the filter presented to the low frequency signal is relatively high) and/or by providing a network that would pass the desired inter modulated tone to the input of the active device (e.g. FET gate).

In order to measure the variation of gate voltage with output power, the gate voltage bias voltage source 321 may comprise a relatively high impedance voltage source, as may be the case where the impedance is used to limit the gate current.

Embodiments of the detector apparatus may be used to detect the output power from any type of amplifier, whether tube, solid state or a combination of both, and in any system in which the amplifier is used, including radio transmitters and any other applications.

Other aspects and embodiments of the present invention comprise any one or more feature(s) disclosed herein in combination with any one or more other feature. In any aspect or embodiment of the invention described herein, any one or more components may be omitted completely or substituted by a variant of by an equivalent feature.

Numerous modifications and changes to the embodiments described above will be apparent to those skilled in the art.

1. An apparatus for detecting output power from an amplifier, comprising:
a first controller for controlling output power from said amplifier;
measuring means for measuring DC bias current/voltage at an output of said amplifier;
a second controller operative to set said first controller to a setting corresponding to an output power at a finite level; and
determining means for determining whether or not there is output power from said amplifier based on the measured DC bias current/voltage at said setting.

2. An apparatus as claimed in claim 1, wherein said finite level is selected to provide a DC bias current/voltage different from that at a lower O/P level.

3. An apparatus as claimed in claim 2, wherein said finite level is sufficient to at least partially saturate said amplifier.

4. An apparatus as claimed in claim 1, wherein said determining means is adapted to make said determination based on a set value.

5. An apparatus as claimed in claim 1, wherein said finite level is a first predetermined level, said second controller is adapted to control said first controller to successively set said output power at said first predetermined level and a second level, different from said first level, and said determining means is adapted to determine whether or not there is output power from said amplifier based on the measured DC bias current/voltage at said different levels.

6. An apparatus as claimed in claim 5, wherein said first and second different levels are selected to cause said DC bias current/voltage to have different values at said first and second levels if there is output power from said amplifier.

7. An apparatus as claimed in claim 6, wherein said determining means determines that there is output power if said values of DC bias current/voltage are different.

8. An apparatus as claimed in claim 5, wherein said determining means comprises ratio determining means for determining the ratio of said first and second measured values of DC bias current/voltage.

9. An apparatus as claimed in claim 8, wherein said determining means further comprises comparing means for comparing the ratio with a predetermined threshold value.

10. An apparatus as claimed in claim 9, wherein said determining means determines that there is output power from said amplifier if said measured ratio equals or exceeds said predetermined threshold value.

11. An apparatus as claimed in claim 5, further comprising an interface for receiving a user command, and said second controller is responsive to said user command to successively set said output power at said first and second different levels.

12. An apparatus as claimed in claim 1, further comprising an interface for receiving a user command, and said second controller is responsive to said user command to set said output power at said finite level.

13. An apparatus as claimed in claim 1, further comprising indicator means for indicating whether or not there is output power from said amplifier as determined by said determining means.

14. An apparatus as claimed in claim 1, further comprising means for determining the value of at least one of said first and second output power levels based on the value of another parameter.

15. An apparatus as claimed in claim 14, wherein said other parameter comprises an operating parameter for said amplifier.

16. An apparatus as claimed in claim 15, wherein said operating parameter comprises a maximum value for said output power.

17. An apparatus as claimed in claim 1, wherein said first controller comprises at least one of a controller for controlling the level of input signal to said amplifier and gain controller for controlling the gain of said amplifier.

18. An apparatus as claimed in claim 1, wherein said measuring means comprises resistance means for carrying said DC bias current, and means for measuring the voltage across said resistor.

19. An apparatus for detecting output power from an amplifier, comprising:
measuring means for measuring bias current/voltage of said amplifier; and
determining means for determining if there is output power from said amplifier based on the measured bias current/voltage.

20. An apparatus as claimed in claim 19, further comprising a controller for controlling output power from said amplifier, wherein said controller is adapted to set said output power at a predetermined value.

21. (canceled)

22. An apparatus for detecting output power from an amplifier, comprising a controller adapted to set the output power from said amplifier to a predetermined level for said detection, and measuring means for measuring the DC bias current at said predetermined level.

23. An apparatus as claimed in claim 22, wherein said controller is responsive to a user command to set the output power of said amplifier to said predetermined level.

24. An apparatus as claimed in claim 22, wherein said controller is adapted to successively set the output power of said amplifier to a plurality of predetermined different levels, including said predetermined level, and said measuring means is capable of measuring said DC bias current/voltage at said plurality of different levels.

25. An apparatus as claimed in claim 22, further comprising determining means for determining if there is output power from said amplifier based on said measured DC bias current/voltage at said predetermined level or levels.

26. (canceled)

27. An apparatus as claimed in claim 1, further comprising means for determining the value of output power from said amplifier based on at least one measured value of DC bias current/voltage.

28. An apparatus as claimed in claim 27, wherein said determining means is adapted to determine the value of output power from said amplifier based on a predetermined relationship between output power and DC bias current/voltage.

29. An apparatus for measuring output power from an amplifier, comprising measuring means for measuring DC bias current/voltage of said amplifier, and determining means for determining from said measured bias current/voltage the value of output power from said amplifier.

30. (canceled)

31. An apparatus as claimed in claim 1, further comprising means for providing a signal to the input of said amplifier.

32. An apparatus as claimed in claim 31, wherein said means is capable of providing a modulated signal or a modulated carrier wave signal to the input of said amplifier.

33. A method of detecting output power from an amplifier comprising the steps of:
(a) supplying an input signal to be amplified to said amplifier;
(b) setting a controller for controlling output power from said amplifier to a setting corresponding to a predetermined level of output power from the amplifier;
(c) measuring the DC bias current/voltage at an output of said amplifier at said predetermined level; and
(d) determining whether or not there is output power from said amplifier based on said value of DC bias current/voltage measured at said predetermined level.

34. A method as claimed in claim 33, wherein said predetermined level is selected to provide a value of DC bias current/voltage that is indicative of the presence of output power from said amplifier if there is output power from said amplifier.

35. A method as claimed in claim 34, wherein said level is selected to provide a value of DC bias current/voltage that can be distinguished from another value of DC bias current/voltage if there is power from said amplifier.

36. A method as claimed in claim 33, wherein said predetermined level is sufficient to at least partially saturate said amplifier.

37. A method as claimed in claim 33, wherein said determining step comprises making said determination based on a further value.

38. A method as claimed in claim 37, wherein said further value comprises one of: (1) an expected value for said bias current/voltage if there is output power from said amplifier, (2) a value for bias current/voltage different than expected if there is output power from said amplifier, (3) a predetermined value and (4) a measurement value of DC bias current/voltage at a second power level setting, different from said first level.

39. A method as claimed in claim 33, further comprising:
(e) setting a controller for controlling output power from said amplifier to a setting corresponding to a second level of output power from the amplifier, the second level being different from said first predetermined level;
(f) measuring the DC bias current/voltage at an output of said amplifier at said second level; and
(g) making said determination based on the measured DC bias current/voltage at said second level.

40. A method as claimed in claim 39, wherein said first and second different levels of output power are selected to cause said DC bias current/voltage to have different values at said first and second levels if there is output power from said amplifier.

41. A method as claimed in claim 40, wherein the step of determining comprises determining that there is output power if said values of DC bias current/voltage are different.

42. A method as claimed in claim 39, wherein said determining step comprises determining the ratio of said first and second measured values of DC bias current/voltage.

43. A method as claimed in claim 42, wherein said determining step further comprises comparing said ratio with a predetermined value.

44. A method as claimed in claim 42, wherein said predetermined value is one of (1) an expected value for said ratio if there is output power from said amplifier, and (2) a value for said ratio if the DC bias current/voltage is different than expected if there is output power from said amplifier.

45. A method as claimed in claim 39, further comprising performing at least steps (b) and (e) in response to a single user input command.

46. A method as claimed in claim 33, further comprising providing an indication detectable by a user as to whether or not there is output power from said amplifier as determined by said determining step.

47. A method as claimed in claim 33, further comprising determining the value for at least one of said first and second output power levels based on the value of another parameter.

48. A method as claimed in claim 47, wherein said other parameter comprises an operating parameter for said amplifier.

49. A method as claimed in claim 48, wherein said operating parameter comprises a maximum value for said output power.

50. A method as claimed in claim 33, wherein said controller in step (b) comprises at least one of a controller for controlling the level of input signal to said amplifier and a gain controller for controlling the gain of said amplifier.

51. A method as claimed in claim 39, wherein said controller for controlling output power from said amplifier in step (e) comprises at least one of a controller for controlling the level of input signal to said amplifier and a gain controller for controlling the gain of said amplifier.

52. A method as claimed in claim 33, wherein measuring the DC bias current/voltage in step (c) comprises measuring the voltage across a resistance means carrying said DC bias current.

53. A method as claimed in claim 33, comprising selecting an operating point for said amplifier in which the value of DC bias current/voltage is greater at a predetermined output power level than the DC bias level at said predetermined output power level for another operating point.

54. A method as claimed in claim 33, further comprising determining the value of output power from said amplifier based on a measured value of DC bias current/voltage.

55. A method as claimed in claim 54, comprising making said determination from a predetermined relationship between DC bias current and output power level.

56. A method of detecting output power from an amplifier comprising applying a signal to be amplified to said amplifier, said signal being conditioned to provide a predetermined O/P from said amplifier, measuring bias current/voltage of said amplifier, and determining if there is power from said amplifier based on the value of said measured DC bias current/voltage.

57. (canceled)

58. A method of measuring the output power from an amplifier comprising applying a signal to be amplified to said amplifier, measuring bias current/voltage of said amplifier when applying said signal, and determining the value of output power from said amplifier or a parameter based thereon based on the measured value of bias current/voltage.

59. A method as claimed in claim 58, wherein said determination is based on a predetermined relationship between bias current/voltage and output power.

60. A method as claimed in claim 59, wherein said predetermined relationship comprises at least one of a table of values of bias current/voltage and corresponding values of output power or parameter based thereon, and a mathematical relationship.

61. A method as claimed in claim 33, wherein the signal applied to said amplifier is a modulated tone.

62. (canceled)

63. (canceled)

64. (canceled)

65. An apparatus for detecting output power from the signal output of an active device, comprising sensor means for sensing a parameter associated with said device, said parameter being different from a parameter of an output signal from the signal output and dependent on output power of an output signal from the signal output of the device, and determining means for making a determination indicative of whether there is output power from the device based on the value of the sensed parameter.

66. An apparatus as claimed in claim 65, wherein said parameter comprises any of: (a) a temperature of said device; (b) bias voltage of a control terminal of the device; (c) bias current to a control terminal of the device; (d) DC or low frequency current through a non-control terminal of said device; and (e) DC or low frequency voltage of a non-control terminal of said device.

67. An apparatus as claimed in claim 65, further comprising means for applying a low frequency signal to said device, wherein said sensor is adapted to measure a resulting low frequency signal output from a terminal of said device.

68. An apparatus as claimed in claim 67, wherein said means comprises means for applying first and second tone signals to said device, said second tone having a different frequency to said first tone.

69. (canceled)

70. An apparatus as claimed in claim 1, further comprising a controller which sets the bias level of said amplifier at a first level at which the difference between first and second values of dc bias current/voltage at first and second output power levels, respectively, is greater than the difference between first and second values of dc bias current/voltage at said first and second output power levels, respectively, at a second bias level.

71. An apparatus as claimed in claim 70, wherein the first bias level is below the second bias level.

72. A method as claimed in claim 33, further comprising setting the bias level of said amplifier at a first level at which the difference between first and second values of dc bias current/voltage at first and second output power levels, respectively, is greater than the difference between first and second values of dc bias current/voltage at said first and second output power levels, respectively, at a second bias level.

73. A method as claimed in claim 72, wherein the first bias level is below the second bias level.
